(19) United States
(12) Patent Application Publication
(10) Pub. No.: US 2015/0041676 A1
(43) Pub. Date: Feb. 12, 2015

(54) SOUNDPROOF COVER FOR CHARGED-PARTICLE BEAM DEVICE, AND CHARGED-PARTICLE BEAM DEVICE

(71) Applicant: HITACHI HIGH-TECHNOLOGIES CORPORATION, Tokyo (JP)

(72) Inventors: Daisuke Muto, Tokyo (JP); Hideki Kikuchi, Tokyo (JP); Kota Ueda, Tokyo (JP); Isao Nagaoki, Tokyo (JP); Yasushi Takano, Tokyo (JP)

(73) Assignee: HITACHI HIGH-TECHNOLOGIES CORPORATION, Tokyo (JP)

(21) Appl. No.: 14/378,688

(22) PCT Filed: Feb. 18, 2013
(86) PCT No.: PCT/JP2013/053788

§ 371 Date: Aug. 14, 2014

(30) Foreign Application Priority Data
Mar. 13, 2012 (JP) 2012-055233

(51) Int. Cl. H01J 37/16; H01J 37/20; H01J 37/26; G10K 11/16

(52) U.S. Cl. CPC H01J 37/16; G10K 11/16; H01J 37/20; H01J 37/26
USPC 250/453.11; 181/202

(57) ABSTRACT

It is an object of the present invention to provide a noise-proof cover and a charged particle beam apparatus that realize both of suppression of an image failure caused by a specific frequency and a reduction in size. To attain the object, the present invention proposes a noise-proof cover that surrounds a charged particle beam apparatus, the noise-proof cover including a hollow section forming member that forms a cylindrical body having a wall surface extending along an inner wall of the noise-proof cover, one end of the cylindrical body formed by the hollow section forming member being opened and the other end of the cylindrical section being closed, and the charged particle beam apparatus surrounded by the noise-proof cover.

### TECHNICAL FIELD

The present invention relates to a noise-proof cover used in a charged particle beam apparatus and, more particularly, to a noise-proof cover that can suppress the influence of sound having a specific frequency and a charged particle beam apparatus.

### BACKGROUND ART

In a charged particle beam apparatus such as an electron microscope for performing observation of a microstructure at high resolution using an electron beam, occurrence of an image failure is revealed by very small vibration or sound from the outside according to improvement of resolution. Therefore, for the purpose of preventing occurrence of an image failure caused by emission of setting environment sound, a noise-proof cover for covering an apparatus from the outer side is set as means for blocking transmission of a sound wave emitted to the apparatus.

The noise-proof cover usually forms a hexahedral structure having upper and lower, left and right, and upper and lower surfaces taking into account a wraparound characteristic of a sound wave and in view of workability and a reduction in costs.

To improve noise-proof performance of the cover, it is effective to absorb sound on the inside of the cover and stretch an organic porous material around the inner surface of the cover. However, in general, the charged particle beam apparatus is used in a clean room. In some case, dusting characteristics due to a spray of the organic material hinder dust resistance of the clean room to cause a problem. As means for preventing this problem, a technique for covering a sound absorbing material with dust-proof fiber and attaching the sound absorbing material to the inner surface of the noise-proof cover is disclosed in PTL 1.

In general, in the field of acoustical engineering, it is known that a resonance frequency depending on the shape of a container because of air vibration in a mouth portion of the shape of a flask-shaped container is present. This is called Helmholtz resonator. There is a technique for absorbing sound making use of this sound absorption principle. For example, as a sound absorption structure that makes use of this technique, a sound absorption structure made of a box member including a large number of small holes is disclosed in PTL 2. A structure in which the Helmholtz resonator is set in a sash portion of a double window is disclosed in PTL 3 and PTL 4. A structure in which the Helmholtz resonator is set in a lower part of a skirt portion of a railway car is disclosed in PTL 5.

### CITATION LIST

### Patent Literature

PTL 1: JP-A-2006-79870

PTL 2: JP-A-2008-138505

PTL 3: Japanese Patent No. 4232153

PTL 4: JP-A-2010-216104

PTL 5: Japanese Patent No. 3911208

### SUMMARY OF INVENTION

### Technical Problem

In a charged particle beam apparatus having high resolution, a noise-proof cover is set as means for blocking transmission of a sound wave emitted to an apparatus. Consequently, noise resistant performance for a relatively high frequency is improved. However, on the other hand, noise resistant performance is sometimes deteriorated in a low-frequency region. This is caused because, whereas, in general design, a part sensitive to vibration in an apparatus is arranged near a cover center, since an anti-node of a sound pressure of an acoustic standing wave generated in the cover is present exactly in the cover center at a certain frequency, the part sensitive to vibration is excited.

When the vibration caused by the sound at the specific frequency is treated by the noise-proof cover of PTL 1, the thickness of the sound absorbing material to be set increases because a target frequency is low. In the conventional technique disclosed in PTL 2, it is necessary to open innumerable holes having an opening diameter equal to or smaller than a plate thickness. Since it is difficult to open the holes with general punching, laser machining needs to be separately performed. As a result, it is likely that manufacturing costs increase. Further, in PTL 3 or PTL 5, a structure such as a shape and a setting place for enabling efficient sound absorption is not provided by a sound absorption structure specialized for a frequency that causes a problem in the charged particle beam apparatus.

A noise-proof cover and a charged particle beam apparatus having an object of realizing both of suppression of an image failure caused by a specific frequency and a reduction in size are explained below.

### Solution to Problem

As an aspect for attaining the object, there is proposed below a noise-proof cover that surrounds a charged particle beam apparatus, the noise-proof cover including a hollow section forming member that forms a cylindrical body having a wall surface extending along an inner wall of the noise-proof cover, one end of the cylindrical body formed by the hollow section forming member being opened and the other end of the cylindrical section being closed, and a charged particle beam apparatus surrounded by the noise-proof cover.

### Advantageous Effect of Invention

With the configuration explained above, it is possible to provide the noise-proof cover and the charged particle beam apparatus that do not need a thick sound absorbing material or the like, have small sizes, and suppress an image failure caused by a specific frequency.

### BRIEF DESCRIPTION OF THE DRAWINGS

FIG. 1 is a configuration diagram of a charged particle beam apparatus.

FIG. 2 is a diagram showing a frequency characteristic of noise resistance performance of the charged particle beam apparatus.

FIG. 3 is a diagram showing an example in which a noise-proof cover is set around the charged particle beam apparatus.

FIG. 4 is a diagram showing the influence of the noise-proof cover on the noise resistance performance.

FIG. 5 is a diagram showing a relation between the charged particle beam apparatus and an acoustic standing wave generated in the noise-proof cover.

FIG. 6 is a diagram showing an example of the charged particle beam apparatus around which the noise-proof cover is set.

FIG. 7 is a diagram for explaining details of a noise-proof cover section.

FIG. 8 is a diagram for explaining a numerical analysis model for verifying an effect of the noise-proof cover.

FIG. 9 is a diagram for explaining a result of a numerical analysis for verifying an effect in a first embodiment of the present invention.

FIG. 10 is another diagram for explaining the result of the numerical analysis for verifying the effect of the noise-proof cover.

FIG. 11 is a diagram showing another example of the charged particle beam apparatus around which the noise-proof cover is set.

FIG. 12 is a diagram showing still another example of the charged particle beam apparatus around which the noise-proof cover is set.

FIG. 13 is a diagram showing still another example of the charged particle beam apparatus around which the noise-proof cover is set.

FIG. 14 is a diagram showing still another example of the charged particle beam apparatus around which the noise-proof cover is set.

### DESCRIPTION OF EMBODIMENTS

An embodiment explained below relates to a charged particle beam apparatus in which an image failure occurs because of acoustic excitation. As an example, the embodiment relates to a noise-proof cover for reducing noise and vibration from an outside environment. In particular, it is assumed that the noise-proof cover is used in a clean room or the like.

In particular, in this embodiment, concerning a noise-proof cover for a high-resolution charged particle beam apparatus set for the purpose of preventing occurrence of an image failure caused by setting environment sound, a structure for evenly improving noise resistance performance over all frequency bands and realized inexpensively without spoiling dust resistance enough for use in a clean room, which is a setting environment of the charged particle beam apparatus, and easiness of cover opening and closing that takes into account maintenance.

More specifically, in this embodiment, concerning a charged particle beam apparatus configured by an electron gun, a sample chamber, and a detector and a noise-proof cover that covers the outer side of the charged particle beam apparatus, an example is explained in which the charged particle beam apparatus can discriminate an object equal to or smaller than 100 nm and can perform observation at extremely high resolution, the electron gun or the detector or both of the electron gun and the detector are arranged at an end of the apparatus, the sample chamber is arranged in the center of the apparatus, the noise-proof cover has cylindrical hollow sections, one sides of which are opened and the other sides of which are closed with respect to an inner surface, and opening portions of the cylindrical hollow sections are arranged to be present at up, down, left, and right direction ends or up, down, left, and right direction centers in a cover inside or both of the ends and the centers.

The noise-proof cover including a hollow section forming member that forms cylindrical bodies having the wall surfaces extending along the inner wall of the noise-proof cover, one ends of the cylindrical bodies formed by the hollow section forming member being opened and the other ends of the cylindrical bodies being closed, as explained above can efficiently eliminate the influence of sound caused in the cover. Specifically, it is possible to set, in the position of an anti-node of a sound pressure of an acoustic standing wave generated in the cover, a sound absorbing mechanism having a large sound absorption characteristic at a generated frequency of the acoustic standing wave. The noise-proof cover explained in detail below is effectively applied to, in particular, a charged particle beam apparatus having high resolution and can prevent occurrence of an image failure caused by setting environment sound.

The noise-proof cover explained below can improve noise resistant performance evenly over all frequency bands. It is possible to inexpensively provide the noise-proof cover without spoiling dust resistance enough for use in a clean room, which is a setting environment of the charged particle beam apparatus, and easiness of cover opening and closing that takes into account maintenance.

The charged particle beam apparatus explained below indicates apparatuses that perform high-accuracy inspection, observation, and machining such as a general purpose scanning electron microscope, a transmission electron microscope, a measuring apparatus (CD-SEM), a review apparatus, a defect inspection apparatus, and a sample machining apparatus using a charged particle beam and refers to an apparatus in general in which an image failure is caused by very small vibration of the apparatus.

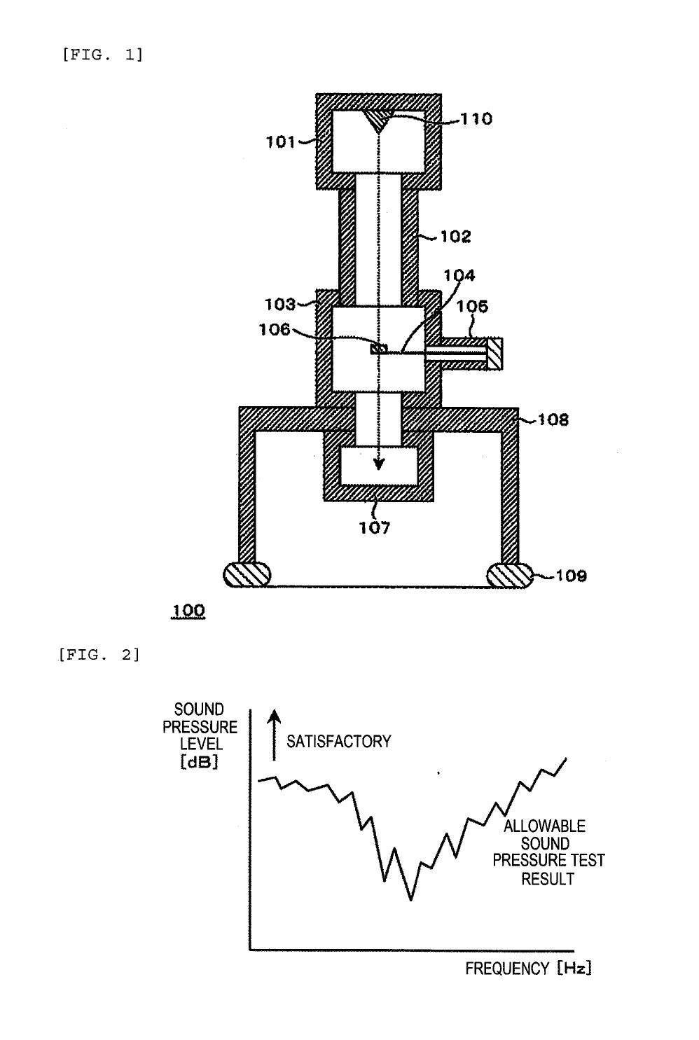

FIG. 1 is a schematic diagram showing an overall configuration of a transmission electron microscope, which is an example of a charged particle beam apparatus 100. The transmission electron microscope shown in FIG. 1 includes a column 101, a convergence device 102, a sample chamber 103, a stage 104, a holder 105, a sample 106, a detector 107, a stand 108, and a vibration damping base 109. Electrons emitted from an electron gun 110 (a charged particle source) present in the column 101 are transmitted through the sample 106 and detected by the detector 107. When a method of applying an electromagnetic field in the convergence device 102 is changed, an orbit of the electrons emitted from the electron gun 110 is very slightly distorted. Therefore, a position where the electrons are transmitted through the sample 106 very slightly changes. The intensity of the electrons detected by the detector 107 changes according to the change in the position. In this way, the intensity of the electrons transmitted through the sample 106 is imaged as light and shade with respect to a coordinate corresponding to the intensity. Consequently, it is possible to obtain an enlarged image of a microstructure of the sample.

Since the charged particle beam apparatus is an imaging apparatus as explained above, main performance of the charged particle beam apparatus is resolution. However, since a very small structure is enlarged and displayed, an image failure is caused by an extremely trivial disturbance. The vibration damping base 109 is set to prevent an image failure caused by vibration from a floor. As an effect of the vibration damping base 109, the image failure due to the floor vibration is reduced. On the other hand, according to improvement of resolution to be higher in definition, in particular, in a recent high-resolution model, that realizes resolution equal to or smaller than 100 nm, an image failure caused by setting environment sound of the charged particle beam apparatus is also revealed.

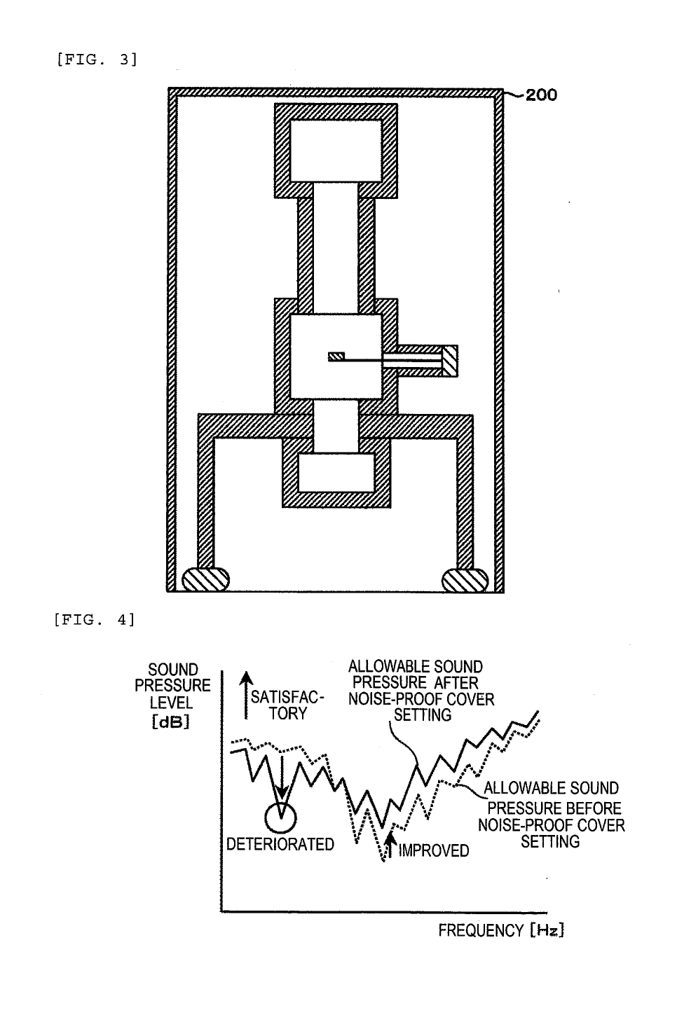

A correspondence relation between the setting environment sound and an amount of the image failure is explained below. An emitted sound pressure and an amount of an image failure at the time when a sound wave is emitted to the charged particle beam apparatus are measured and grasped. A sound pressure obtained by calculating, on the basis of a correspondence relation between the emitted sound pressure and the amount of the image failure, a setting environment sound of which dB or less is required to reduce a degree of the image failure to a predetermined value or less is referred to as “allowable sound pressure”. A larger value of the “allowable sound pressure” means that predetermined resolution can be secured even in a poor environment and indicates that noise resistance performance is high. FIG. 2 is an example showing the “allowable sound pressure”. In general, it is known that the “allowable sound pressure” has a frequency characteristic and, in particular, the frequency characteristic of the “allowable sound pressure” is convex downward at a certain frequency. The phenomenon in which the frequency characteristic of the allowable sound pressure is convex downward at a certain frequency indicates that an image failure tends to be caused by setting environment sound at this frequency. This is because there is a part easily vibrating at this frequency somewhere in the structure of the charged particle beam apparatus and the part is affected by the peculiar vibration. In the case of the transmission electron microscope, in general, this is caused by peculiar vibration of the holder 105. A frequency at which the allowable sound pressure falls often coincides with a peculiar vibration frequency of the holder 105.

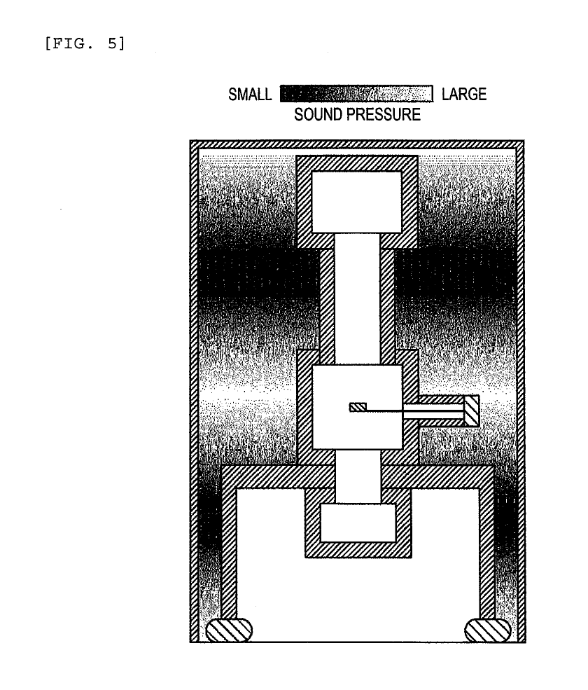

As a method of improving resistance against the image failure caused by the setting environment sound, that is, noise resistance performance, recently, a noise-proof cover 200 shown in FIG. 3 is set around the high-resolution charged particle beam apparatus. By setting the noise-proof cover 200, the noise resistance performance in a wide range is improved at a high frequency. The fall of the allowable sound pressure due to the peculiar vibration of the sections of the structure of the charged particle beam apparatus is reduced.

However, as shown in FIG. 4, whereas the noise resistance performance is improved in a high-frequency region by setting the noise-proof cover 200, in particular, in a limited frequency band of a low-frequency region, a phenomenon is recognized in which the noise resistance performance is deteriorated to the contrary.

This is because an acoustic standing wave shown in FIG. 5 is generated in the cover. Whereas a part sensitive to vibration in an apparatus is arranged near a cover center in general design, since an anti-node of a sound pressure of the acoustic standing wave generated in the cover is present exactly in the cover center, the part sensitive to vibration is excited. Therefore, the phenomenon is caused.

In embodiments explained below, a structure for effectively reducing an intra-cover acoustic sanding wave taking advantage of the fact that the acoustic standing wave generated in the cover is generated at a frequency determined by a dimension of the cover. The embodiments are explained below with reference to the drawings.

### First Embodiment

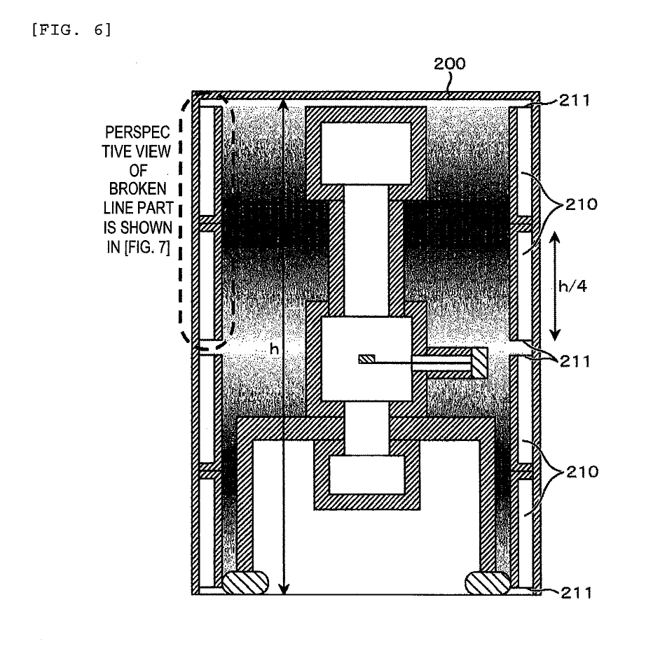

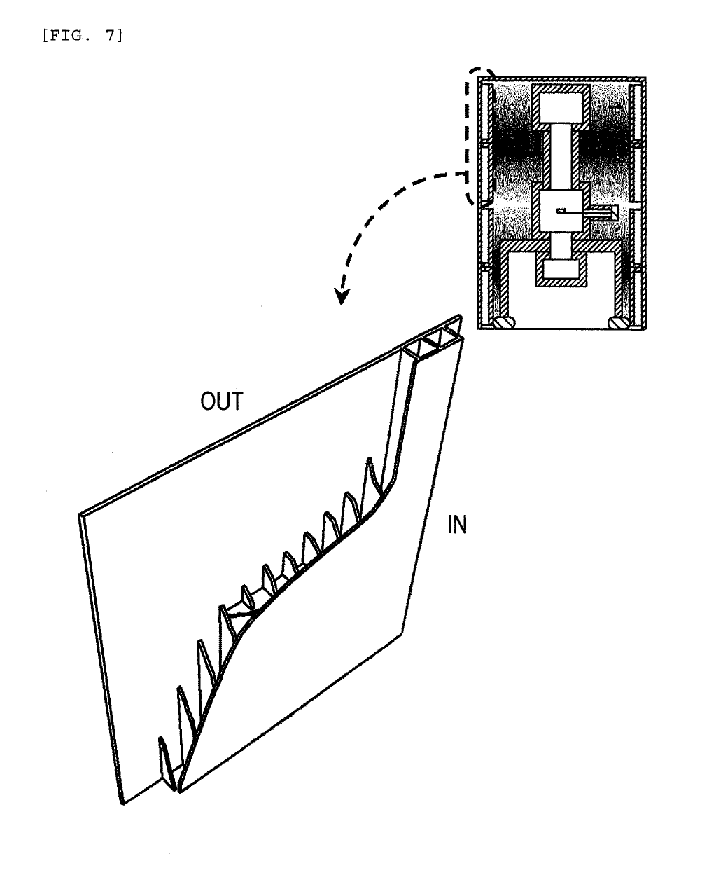

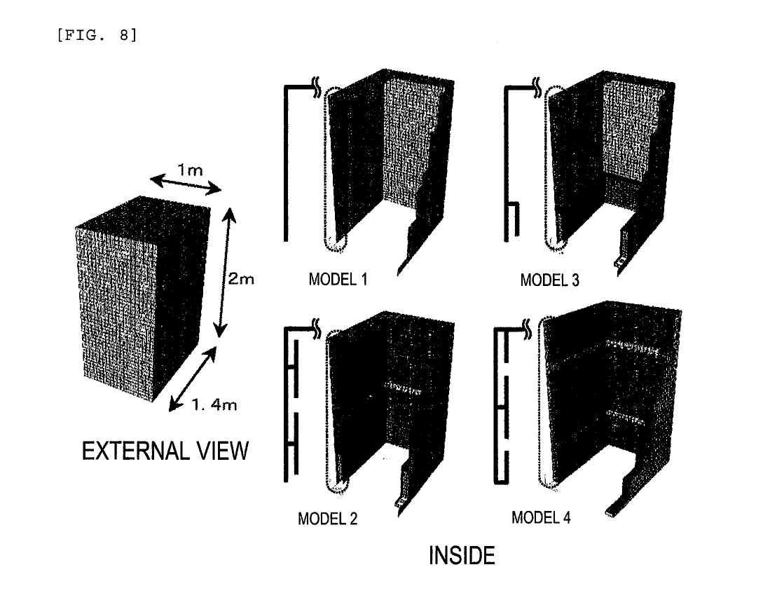

In this embodiment, an embodiment of a noise-proof cover structure that can effectively reduce an intra-cover acoustic standing wave and a charged particle beam apparatus including the noise-proof cover structure is explained with reference to FIGS. 6 and 7.

FIG. 6 is an example of a sectional view of a configuration of the charged particle beam apparatus and a noise-proof cover for the charged particle beam apparatus in this embodiment. A perspective view of a portion indicated by a broken line is shown in FIG. 7. In the embodiment shown in FIG. 6, cylindrical hollow sections 210, one sides of which are closed and the other sides of which are opened with respect to a cover inner surface are set on a sidewall inner surface of the noise-proof cover such that opening sections 211 of the cylindrical hollow sections 210 are present on the upper surface and the lower surface inside the cover and cover upper and lower direction centers at anti-nodes of a sound pressure of an acoustic standing wave. A noise-proof panel illustrated in FIG. 7 is set on a noise-proof cover inner wall surrounding the charged particle beam apparatus and is formed such that a plurality of cylindrical bodies having wall surfaces extending along the inner wall of the noise-proof cover are arrayed along the noise-proof cover inner wall. The noise-proof panel is formed such that the closed sides of the cylindrical bodies are coupled to the closed sides of the other cylindrical bodies. In the case of this embodiment, the noise-proof panel is a hollow section forming member. However, the hollow section forming member is not limited to this and may be other cylindrical bodies that can display effects explained below.

As explained above, among the charged particle beam apparatuses, in particular, in the transmission electron microscope, the portion of the holder 105 is susceptible to vibration because of the structure of the transmission electron microscope. Therefore, the noise resistance performance is lower near the peculiar frequency of the holder 105 than at frequencies around the peculiar frequency. The deterioration in the noise resistance performance at this frequency is reduced by setting the noise-proof cover 200. However, at another frequency lower than the peculiar frequency of the holder 105, an acoustic standing wave having an anti-node of a sound pressure near the cover center where the holder is arranged is generated and the noise resistance performance is deteriorated. Incidentally, the generated frequency of the acoustic standing wave (an acoustic mode) having the anti-node of the sound pressure in the cover center where the holder is arranged depends on the shape and the dimension of the cover. For example, in a 2nd mode in vertical direction, when the height of the cover is represented as h [m], the generated frequency is 340/h [Hz]. If the height of the cover is set to 2 [m], the generated frequency in the 2nd mode in vertical direction is 170 [Hz].

On the other hand, it is known that, when sound having a wavelength four times as long as the length of a cylinder, one side of which is closed and the other side of which is opened, arrives, the cylinder emits sound having an opposite phase of a phase of the arriving sound wave again to thereby cancel the original arriving sound and reduce (absorb) the arriving sound. This is called an acoustic tube. When the length of the acoustic tube is represented as l [m], a frequency at which the acoustic tube displays a sound absorption effect most is 340/41 [Hz].

When the standing wave in the 2nd mode in vertical direction generated in the cover having the height h [m] is effectively absorbed using the acoustic tube, the length l [m] is 1=h/4 [m] and is exactly length for equally dividing the height direction. To display the sound absorption effect to the maximum, it is desirable to set the opening sections 211 in the positions of anti-nodes of a sound pressure. In the 2nd mode in vertical direction, the opening sections are arranged to be present on the cover upper inner surface, the cover lower inner surface, and the cover inner height direction center.

In this embodiment, two noise-proof panels illustrated in FIG. 7 are set on each of sidewalls on four surfaces such that openings are located in a first space in contact with a top plate, a second space located below the first space and including a center region in the height direction of the noise-proof cover, and a third space located below the second space and including a bottom section. The noise-proof panel in this example is formed such that four cylindrical bodies are arrayed in the height direction and the openings are located in each of the first to third spaces. The second space is located in substantially the center of the height direction of the noise-proof cover and is a region where a sample holder (a sample stand) of the transmission electron microscope is located.

When such components are arranged on the cover inner surfaces in the arrangement shown in FIGS. 6 and 7, the cylindrical hollow sections 210 functioning as the acoustic tube do not overlap one another. As a result, it is possible to provide a noise-proof cover structure that can effectively suppress the 2nd mode in vertical direction generated in the cover and evenly improve the noise resistance performance in all frequency bands.

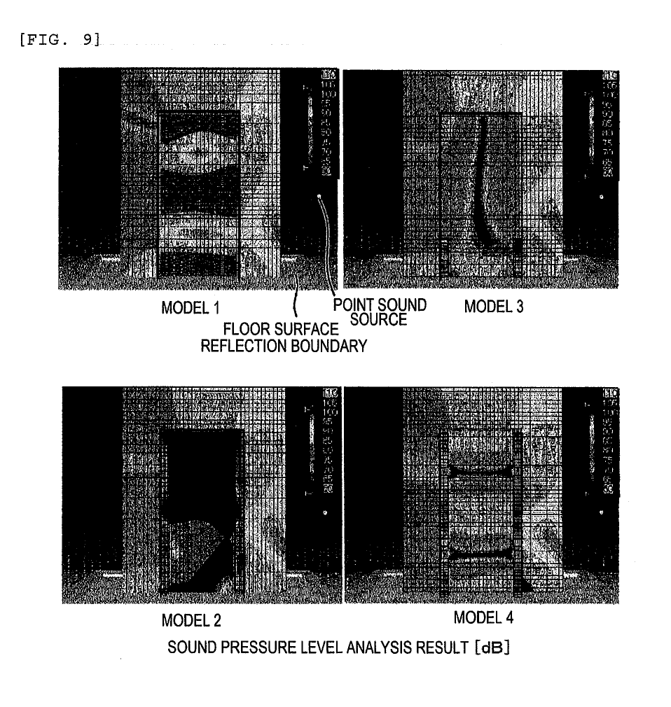

Effects of the structure explained in the first embodiment are explained with reference to FIGS. 8 to 10 concerning a result obtained by verifying the effects using a numerical analysis.

FIG. 8 is an analysis model created to verify the effects of the structure explained in the first embodiment. In the model, only the noise-proof cover is modeled. The cover has height of 2 m, width of 1 m, and depth of 1.4 m equivalent to the height, the width, and the depth of a general transmission electron microscope. Concerning the setting of the acoustic tube on the inside, four types are prepared: a model in which the acoustic tube is not set (a model 1), a model equivalent to the first embodiment (a model 2), a model in which only a lower quarter of the acoustic tube in the first embodiment is set (a model 3), and a model in which the length of the acoustic tube is equal to the length in the first embodiment but the positions of the openings are different (a model 4).

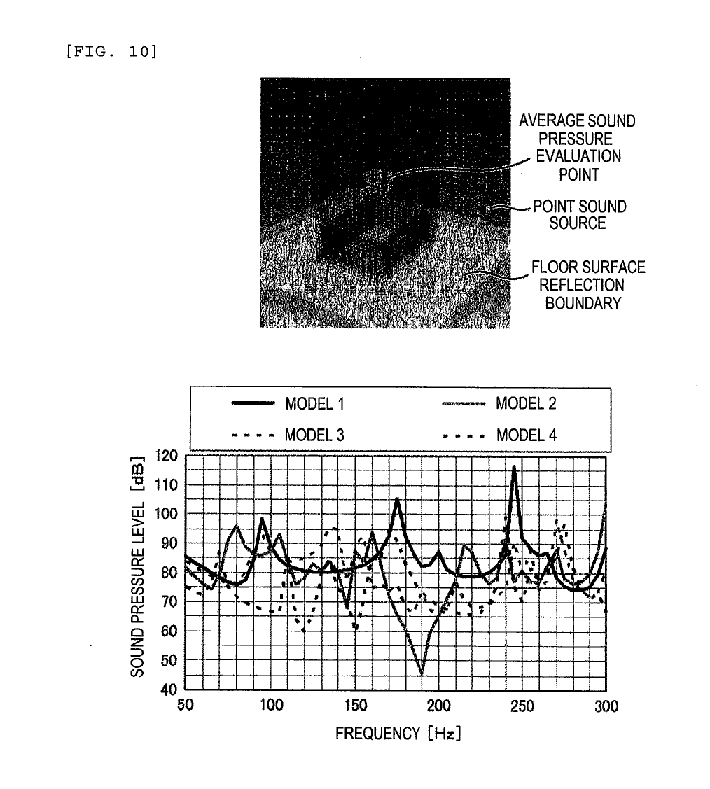

Concerning these models, when a point sound source is arranged in a position of 1 m on the cover side surface outer side and 1 m on the floor and a reflection surface simulating the floor is set in a position 10 mm below the cover lower end, a result obtained by calculating sound leaking from a gap between the floor and the cover and transmitting to the cover inside is shown in FIG. 9. The figure shows a cross section of a sound pressure level (a unit of a contour is [dB]) in the vertical direction at 175 Hz. It is seen that, in the model 1, a 2nd mode in vertical direction is generated at the frequency calculated as explained above. On the other hand, it is seen that, in the model 2 equivalent to the first embodiment, the acoustic standing wave is effectively suppressed. On the other hand, in the model 3, the standing wave is not sufficiently suppressed. In the model 4, the suppression effect is so small that the 2nd mode in vertical direction can be still recognized.

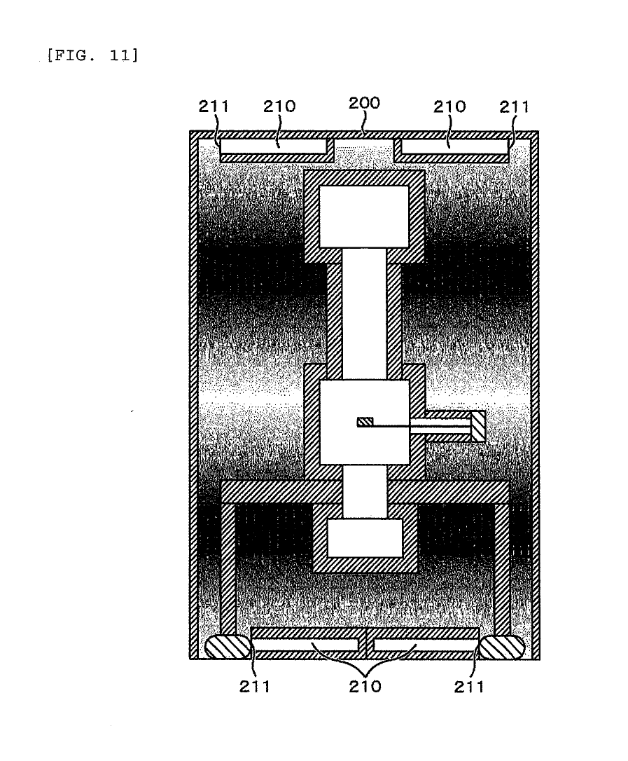

FIG. 10 is a diagram of frequency characteristics of sound pressures concerning the respective models explained above. Average sound pressures at a sound pressure evaluation point shown in the upper figure of FIG. 10 are shown. The frequency characteristics can be explained the same as explained above. The figure indicates that the model 2 equivalent to the first embodiment can reduce the intra-cover noise most at a relevant frequency.

### Second Embodiment

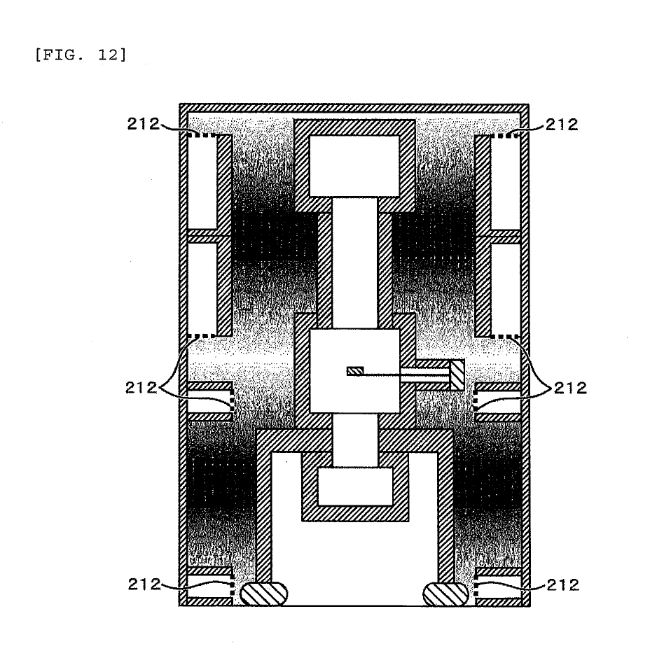

In this embodiment, an example of a structure in which acoustic standing waves in a 2nd mode in vertical direction and a 1st mode in horizontal direction can be suppressed by setting an acoustic tube using not only a side surface but also an inner surface of a ceiling and a floor surface is explained with reference to FIG. 11. In FIG. 11, for the purpose of effectively using an inner surface of a ceiling and a floor surface of the noise-proof cover 200, the length direction of the cylinders of the cylindrical hollow sections 210 in the first embodiment shown in FIG. 6 is set in a cover lateral direction rather than a cover height direction in the cover. Consequently, it is possible to effectively use the inner surface of the ceiling and the floor surface of the noir-proof cover 200. Further, it is possible to reduce the 1st mode in horizontal direction in the cover, although contribution is small. It is expected that it is possible to further reduce an image failure than in the first embodiment.

### Third Embodiment

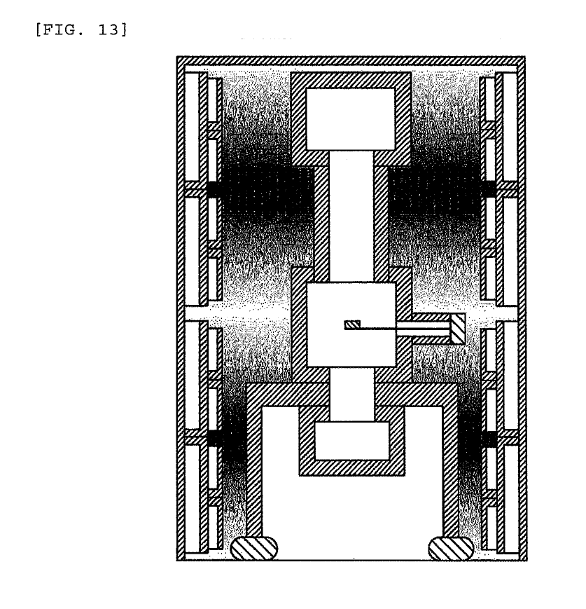

A pattern of combination with perforated panels is explained as another embodiment with reference to FIG. 12. In FIG. 12, an example is shown in which perforated panels are set in the opening sections 211 of the cylindrical hollow sections 210 having the structure shown in FIG. 6 and explained in the first embodiment. By setting the perforated panels in the opening sections in this way, the mobility of air vibrating at the opening sections is suppressed, and thereby it is possible to display a sound absorption effect even in the cylindrical hollow sections having short length compared with the length of the cylindrical hollow section not provided with the perforated panels. Consequently, even when the cylindrical hollow sections cannot be set over the entire cover inner surface, it is possible to display an equivalent sound absorption effect. When an opening ratio of the perforated panels is extremely small, it is possible to reduce the length of the cylindrical hollow sections. Consequently, it is possible to set an opening direction in a direction perpendicular to the cover surface. As a result, a degree of freedom of design increases.

### Fourth Embodiment

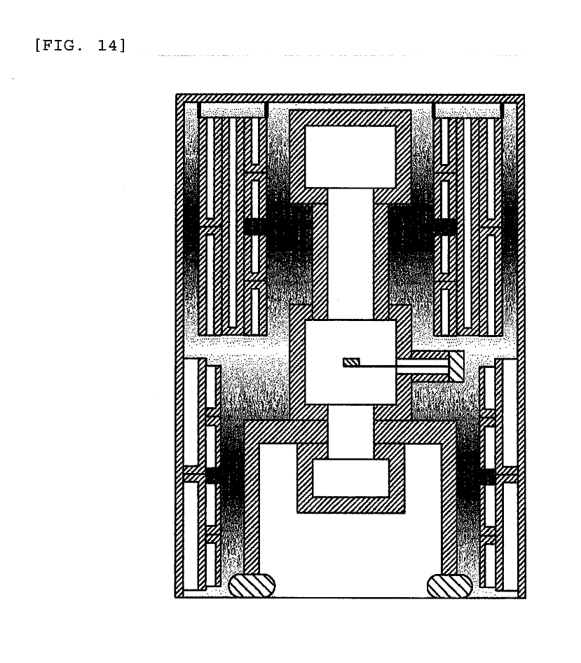

A pattern in which cylindrical hollow sections are set in multiple stages on a noise-proof cover inner surface is explained as still another embodiment with reference to FIG. 13. In FIG. 13, an example is shown in which the cylindrical hollow sections 210 are set again on the inner surfaces of the cylindrical hollow sections 210 set on the inner surface of the noise-proof cover 200 in the structure shown in FIG. 6 and explained in the first embodiment. In this way, the cylindrical hollow sections may be set in multiple stages. The length of the cylindrical hollow sections does not need to be the same as the length of the cylindrical hollow sections in the first stage. The cylindrical hollow sections may be set in multiple stages when the ceiling surface and the floor surface of the noise-proof cover are used as in the second embodiment shown in FIG. 11.

By skillfully setting the multistage structure of the cylindrical hollow sections, it is possible to expect improvement of noise resistance performance in all frequency bands. For example, in the model 2 applied with the first embodiment in the lower figure of FIG. 10, even in a band in which the intra-cover sound pressure rises higher than that in the model 1 not applied with the first embodiment, it is expected that the rise in the intra-cover sound pressure is reduced by setting the cylindrical hollow sections in second and third stages.

### Fifth Embodiment

A pattern in which cylindrical hollow sections arranged in multiple stages are arranged to be suspended from a noise-proof cover ceiling is explained as still another embodiment with reference to FIG. 14. In FIG. 14, an example is shown in which, in the structure shown in FIG. 13 and explained in the fourth embodiment, the multistage structure of the cylindrical hollow sections is suspended from the noise-proof cover ceiling surface using a jig rather than being directly arranged on the noise-proof cover inner surface. A relatively wide space is present in an upper part on the inner side of a noise-proof cover of a charged particle beam apparatus. On the other hand, for convenience of maintenance of the noise-proof cover itself, opening and closing work of the noise-proof cover needs to be easily performed. Therefore, there is a limitation that many structures cannot be set on the inner surface. In such a case, the multistage structure of the cylindrical hollow sections explained in the fourth embodiment may be configured not to be directly set on the noise-proof cover inner surface by, for example, being suspended from the ceiling surface using the jig as shown in the figure.

### REFERENCE SIGNS LIST

100 Charged particle beam apparatus
101 Column
102 Convergence device
103 Sample chamber
104 Stage
105 Holder
106 Sample
107 Detector
108 Stand
109 Vibration damping base
110 Electron gun
200 Noise-proof cover
210 Cylindrical hollow section
211 Opening section of the cylindrical hollow section
212 Perforated panel

1. A noise-proof cover for a charged particle beam apparatus that surrounds the charged particle beam apparatus, the noise-proof cover comprising a hollow section forming member that forms a cylindrical body having a wall surface extending along an inner wall of the noise-proof cover, wherein one end of the cylindrical body formed by the hollow section forming member being opened and the other end of the cylindrical section being closed.

2. The noise-proof cover for the charged particle beam apparatus according to claim 1, wherein the hollow section forming member forms the cylindrical body to array a plurality of the cylindrical bodies along the inner wall of the noise-proof cover.

3. The noise-proof cover for the charged particle beam apparatus according to claim 1, wherein the hollow forming member forms the cylindrical body on a sidewall of the noise-proof cover and forms the cylindrical body such that the opening is located in at least one of a first space in contact with a top plate of the noise-proof cover, a second space including a center region in a height direction of the noise-proof cover, and a third space including a bottom section.

4. The noise-proof cover for the charged particle beam apparatus according to claim 3, wherein at least a quartet of the cylindrical bodies are arrayed in a height direction of the sidewall, the cylindrical body closest to the top plate has an opening in the first space, the cylindrical bodies second and third closest to the top plate have openings in the second space, and the cylindrical body fourth closest from the top plate has an opening in the third space.

5. The noise-proof cover for the charged particle beam apparatus according to claim 4, wherein length of a hollow section of the cylindrical body is set to about ¼ of height of the noise-proof cover.

6. The noise-proof cover for the charged particle beam apparatus according to claim 1, wherein a perforated panel is set in the opening.

7. The noise-proof cover for the charged particle beam apparatus according to claim 1, wherein the hollow forming member forms the cylindrical body in a top plate of the noise-proof cover.

8. The noise-proof cover for the charged particle beam apparatus according to claim 1, wherein the hollow forming member forms the cylindrical body in a bottom section of the noise-proof cover.

9. The noise-proof cover for the charged particle beam apparatus according to claim 1, wherein the hollow section forming member forms a plurality of the cylindrical bodies to be superimposed on an inner side, an outer side or both of the inner side and the outer side of the noise-proof cover in multiple stages.

10. The noise-proof cover for the charged particle beam apparatus according to claim 1, wherein the hollow section forming member forms the cylindrical body on a space on an inner side of the noise-proof cover in one stage or form a plurality of the cylindrical bodies to be superimposed on the space in multiple stages.

11. A charged particle beam apparatus comprising:
a charged particle source; and
a sample stand that retains a sample on which a charged particle beam emitted from the charged particle source is irradiated, wherein
the charged particle beam apparatus includes a noise-proof cover that surrounds the charged particle beam apparatus, the noise-proof cover including a hollow section forming member that forms a cylindrical body having a wall surface extending along an inner wall of the noise-proof cover, one end of the cylindrical body formed by the hollow section forming member being opened and the other end of the cylindrical section being closed.

12. The charged particle beam apparatus according to claim 11, wherein the hollow section forming member forms the cylindrical body to array a plurality of the cylindrical bodies along the inner wall of the noise-proof cover.

13. The charged particle beam apparatus according to claim 11, wherein the hollow forming member forms the cylindrical body on a sidewall of the noise-proof cover and forms the cylindrical body such that the opening is located in at least one of a first space in contact with a top plate of the noise-proof cover, a second space including a center region in a height direction of the noise-proof cover, and a third space including a bottom section.

14. The charged particle beam apparatus according to claim 11, wherein the hollow forming member forms the cylindrical body on a sidewall of the noise-proof cover and forms the cylindrical body such that the opening is located in, among a first space in contact with a top plate of the noise-proof cover, a second space including a center region in a height direction of the noise-proof cover, and a third space including a bottom section, at least the second space.

15. The charged particle beam apparatus according to claim 14, wherein the sample stand is arranged in the second space.
